(19) United States
(12) Patent Application Publication
(10) Pub. No.: US 2006/0157705 A1
(43) Pub. Date: Jul. 20, 2006

(54) Thin film transistor array panel

(76) Inventor: Dong-Hyeon Ki, Chungcheongnam-do (KR)

Correspondence Address: DLA PIPER RUDNICK GRAY CARY US, LLP, 2000 UNIVERSITY AVENUE, E. PALO ALTO, CA, 94303-2248, US

(21) Appl. No.: 11/325,894

(22) Filed: Jan. 4, 2006

(30) Foreign Application Priority Data
Jan. 11, 2005 (KR) 10-2005-0002544

(51) Int. Cl. H01L 29/04; G02F 1/136

(52) U.S. Cl. 257/59; 257/72; 349/43; 257/E27.132

(57) ABSTRACT

A thin film transistor array panel is provided, comprising: a gate line on an insulating substrate; a storage electrode line on the insulating substrate; a gate insulating layer over the gate line and the storage electrode line; a semiconductor layer on the gate insulating layer; a data line and a drain electrode on the semiconductor layer and separated from each other; a lower passivation layer formed on the semiconductor layer and having a first contact hole exposing the drain electrode; a color filter on the lower passivation layer; an upper passivation layer on the color filter and having a second contact hole exposing the drain electrode; and a pixel electrode connected to the drain electrode through the first and second contact holes; wherein the storage electrode line has a light blocking member parallel to the data line.

### BACKGROUND OF THE INVENTION

(a) Field of the Invention

The present invention relates to liquid crystal displays (LCDs). More specifically, the invention relates to a thin film transistor array panel.

(b) Description of the Related Art

Liquid crystal displays are one of the most widely used flat panel displays. An LCD includes two panels provided with field-generating electrodes and a liquid crystal (LC) layer interposed therebetween. The LCD displays images by applying voltages to the field-generating electrodes to generate a directional electric field in the LC layer, which orients LC molecules in the LC layer to adjust polarization of incident light.

Among LCDs employing field-generating electrodes on respective panels, one such LCD is configured with one panel having a plurality of pixel electrodes arranged in a matrix, and another panel having a common electrode covering its entire surface. Image display is accomplished by applying individual voltages to the respective pixel electrodes. For the application of the individual voltages, a plurality of three-terminal thin film transistors (TFTs) is connected to 1) the respective pixel electrodes, 2) a plurality of gate lines transmitting signals for controlling the TFTs, and 3) a plurality of data lines transmitting voltages to be applied to the pixel electrodes are provided on the panel. A color filter is provided in the other panel to display full color images.

It is preferable for the panel to have a high aperture ratio, so as to enhance the brightness of the LCD. To increase the aperture ratio, the color filter is provided on one panel having the thin film transistor, thereby minimizing the align margin of the two panels. At this time, an organic insulating layer having a good flatness characteristic is formed on the color filter to smooth a surface profile thereof.

However, when alignment between the layers is not accurate in a photolithography process for manufacturing the LCD, differences of parasitic capacitances generated between signal lines and pixel electrodes, or at a location between the layers, are generated. This causes differences in the electrical characteristics or aperture ratio between frames, which are exposure units, thereby generating poor image factors such as stripes.

### SUMMARY OF THE INVENTION

The invention can be implemented in numerous ways. Several embodiments of the invention are discussed below.

In one embodiment of the invention, a thin film transistor array panel is provided, comprising: a gate line on an insulating substrate; a storage electrode line on the insulating substrate; a gate insulating layer over the gate line and the storage electrode line; a semiconductor layer on the gate insulating layer; a data line and a drain electrode on the semiconductor layer and separated from the each other; a lower passivation layer formed on the semiconductor layer and having a first contact hole exposing the drain electrode; a color filter on the lower passivation layer; an upper passivation layer on the color filter and having a second contact hole exposing the drain electrode; and a pixel electrode connected to the drain electrode through the first and the second contact holes; wherein the storage electrode line has a light blocking member parallel to the data line.

### BRIEF DESCRIPTION OF THE DRAWINGS

The above and other advantages of the present invention will become more apparent by describing preferred embodiments thereof in detail with reference to the accompanying drawings, in which:

FIG. 1 is a layout view of a TFT array panel for an LCD according to an embodiment of the present invention;

FIG. 2 is a sectional view of the TFT array panel shown in FIG. 1 taken along the lines II-II′;

FIG. 3 is a layout view of a TFT array panel for an LCD according to another embodiment of the present invention;

FIG. 4 is a sectional view of the TFT array panel shown in FIG. 1 taken along the lines IV-IV′;

FIG. 5 is a layout view of a TFT array panel for an LCD according to another embodiment of the present invention;

FIG. 6 is a sectional view of the TFT array panel shown in FIG. 1 taken along the lines VI-VI′;

FIG. 7 is a layout view of a TFT array panel for an LCD according to another embodiment of the present invention;

FIG. 8 is a sectional view of the TFT array panel shown in FIG. 1 taken along the lines VIII-VIII′; and

FIG. 9 is an equivalent circuit diagram of a pixel, gate lines, data lines, and storage lines according to an embodiment of the present invention.

Like reference numerals refer to corresponding parts throughout the drawings. Also, it is understood that the depictions in the figures are diagrammatic and not necessarily to scale.

### DETAILED DESCRIPTION OF EMBODIMENTS

The present invention now will be described more fully hereinafter with reference to the accompanying drawings, in which preferred embodiments of the invention are shown. The present invention may, however, be embodied in many different forms and should not be construed as limited to the embodiments set forth herein.

In the drawings, the thickness of layers, films, and regions are exaggerated for clarity. Like numerals refer to like elements throughout. It will be understood that when an element such as a layer, film, region, or substrate is referred to as being “on” another element, it can be directly on the other element or intervening elements may also be present. In contrast, when an element is referred to as being “directly on” another element, there are no intervening elements present.

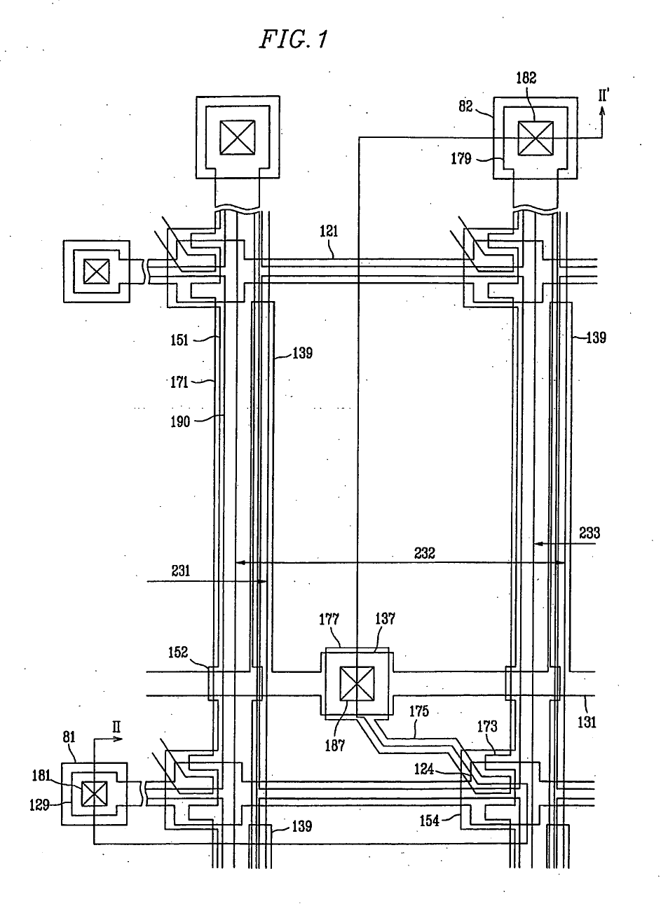

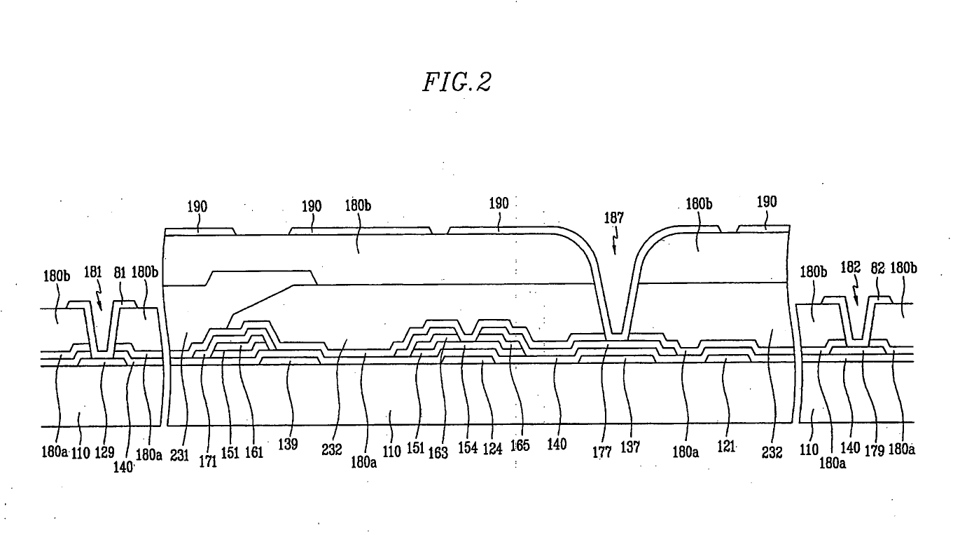

Now, a TFT array panel for an LCD will be described in detail with reference to FIGS. 1 and 2.

FIG. 1 is a layout view of a TFT array panel for an LCD according to an embodiment of the present invention, and FIG. 2 is a sectional view of the TFT array panel shown in FIG. 1 taken along the lines II-II′.

A plurality of gate lines 121 and a plurality of storage electrode lines 131 are formed on an insulating substrate 110 such as transparent glass.

The gate lines 121 extend substantially in a transverse direction, and are separated from each other and transmit gate signals. Each gate line 121 includes a plurality of projections forming a plurality of gate electrodes 124, and an end portion 129 having a large area for contact with another layer or an external driving circuit. The gate lines 121 may extend to be connected to a driving circuit that may be integrated on the insulating substrate 110.

Each of the storage electrode lines 131 which are separated from the gate lines 121 extend substantially in the transverse direction, and are disposed between two adjacent gate lines 121. The storage electrode lines 131 are supplied with a predetermined voltage such as the common voltage of the other panel (not shown). The storage electrode lines 131 include a plurality of expansions 137 having a large area, and a plurality of branches 139 extended near the gate lines 121 adjacent thereto (called “previous gate lines”).

The gate lines 121 and the storage electrode lines 131 are preferably made of an Al-containing metal such as Al and an Al alloy, an Ag-containing metal such as Ag and an Ag alloy, a Cu-containing metal such as Cu and a Cu alloy, a Mo-containing metal such as Mo and a Mo alloy, Cr, Ti, or Ta. The gate lines 121 may have a multi-layered structure including two films having different physical characteristics. One of these two films is preferably made of a low resistivity metal including an Al-containing metal for reducing signal delay or voltage drop in the gate lines 121. The other film is preferably made of a material such as Cr, Mo, a Mo alloy, Ta, or Ti that has good physical, chemical, and electrical contact characteristics with other materials such as indium tin oxide (ITO) or indium zinc oxide (IZO). Good examples of the combination of the two films are a lower Cr film and an upper Al (Al—Nd alloy) film, and a lower Al (Al alloy) film and an upper Mo film.

In addition, the lateral sides of the gate line 121 and the storage line 131 can be tapered, and the inclination angle of the lateral sides with respect to a surface of the substrate 110 is in a range of about 30-80 degrees.

A gate insulating layer 140 preferably made of silicon nitride (SiNx) is formed on the gate lines 121.

A plurality of semiconductor stripes 151 and a plurality of semiconductor islands 157 preferably made of hydrogenated amorphous silicon (abbreviated to “a-Si”) are formed on the gate insulating layer 140. Each semiconductor stripe 151 extends substantially in a longitudinal direction, and has a plurality of projections 154 branched out toward the gate electrodes 124 and a plurality of protrusions 152 disposed on the storage electrode lines 131.

A plurality of ohmic contact stripes and islands 161 and 165 that are preferably made of silicide or n+hydrogenated a-Si heavily doped with an N-type impurity, are formed on the semiconductor stripes 151. Each ohmic contact stripe 161 has a plurality of projections 163, and the projections 163 and the ohmic contact islands 165 are located in pairs on the projections 154 of the semiconductor stripes 151.

The lateral sides of the semiconductor stripes 151 and the ohmic contacts 161 and 165 can be tapered, and the inclination angles thereof are preferably in a range of about 30-80 degrees.

A plurality of data lines 171 and a plurality of drain electrodes 175 are formed on the ohmic contacts 161 and 165 and the gate insulating layer 140.

The data lines 171 for transmitting data voltages extend substantially in the longitudinal direction and intersect the gate lines 121 and the storage electrode lines 131. Each data line 171 has an end portion 179 having a large area for contact with another layer or an external device.

Each drain electrode 175 includes a rectangular expansion 177 at least partially overlapping the expansions 137 of the storage electrode lines 131. The edges of the expansion 177 of the drain electrode 175 are substantially parallel to the edges of the expansion of the storage electrode lines 131. Each longitudinal portion of the data lines 171 includes a plurality of projections such that the longitudinal portion including the projections forms a source electrode 173 partly enclosing an end portion of a drain electrode 175 disposed opposite the expansions 177. Each set of a gate electrode 124, a source electrode 173, and a drain electrode 175 along with a projection 154 of a semiconductor stripe 151 form a TFT having a channel formed in the semiconductor projection 154 disposed between the source electrode 173 and the drain electrode 175.

The branches 139 of the storage electrode lines 131 are extended generally proximate and generally parallel to the data line 171. Portions of the branches 139 of the storage electrode lines 131 overlap the data line 171 and are disposed at the right side of the data line 171 in this embodiment. It is preferable that the overlapping area between the branches 139 and the data line 171 is minimized to reduce unnecessary parasitic capacitance.

The data lines 171 and the drain electrode 175 are preferably made of a refractory metal including Cr, Mo, Ti, Ta, or alloys thereof. They may have a multi-layered structure preferably including a low resistivity film and a good contact film.

Like the gate lines 121, the data lines 171 and the drain electrodes 175 can have tapered lateral sides, and the inclination angles thereof can be in a range of about 30-80 degrees.

In the embodiment shown, ohmic contacts 161 and 165 are interposed only between the underlying semiconductor stripes 151 and the overlying data lines 171 and the overlying drain electrodes 175 thereon, and reduce the contact resistance therebetween. The semiconductor stripes 151 include a plurality of exposed portions not covered by the data lines 171 and the drain electrodes 175, such as those portions located between the source electrodes 173 and the drain electrodes 175. Although the semiconductor stripes 151 are narrower than the data lines 171 at most places, the width of the semiconductor stripes 151 becomes larger near the gate lines 121 and the storage lines 131 as described above, to enhance the insulation between the gate lines 121, the storage electrode lines 131, and the data lines 171, and for preventing disconnections of the data lines 171.

A lower passivation layer 180a preferably made of silicon nitride or silicon oxide is formed on the data lines 171, the drain electrodes 175, and the exposed portions of the semiconductor stripes 151.

A plurality of color filters 231-233 are formed on the lower passivation layer 190a, and are disposed substantially within each pixel. The color filters 231-233 extend substantially along the longitudinal direction along the pixel row and are located between the data lines 171. The color filters 231-233 each represent one of the primary colors such as red, green, and blue, and the edge portions of the color filters 231-233 overlap each other on the data lines 171 to block light leakage between the pixels. The color filters 231-233 are removed on the peripheral area in which the end portions of the gate and data lines are disposed, and have a plurality of openings exposing the drain electrode 175 along with the lower passivation layer 190a. The edge portions of the color filters 231-233 overlapping the data lines 171 have substantially thinner thicknesses than the center portions disposed between the data lines 171 to enhance the step coverage characteristics of the overlying layer and the flatness of the surface of the panel, thereby distorting the alignment of liquid crystal molecules. The overlapping portions of the color filters 231-233 completely cover the data lines 171, but the edge portions of the color filters 231-233 might not overlap or meet each other on the data lines 171.

An upper passivation layer 180b is formed on the color filters 231-233. The upper passivation layer 180b is preferably made of an inorganic insulator such as silicon nitride or silicon oxide, a photosensitive organic material having a good flatness characteristic, or a low dielectric insulating material such as a-Si:C:O and a-Si:O:F formed by plasma enhanced chemical vapor deposition (PECVD).

The upper and lower passivation layers 180a and 180b have a plurality of contact holes 185 and 182 exposing the expansions 177 of the drain electrodes 175 and end portions 179 of the data lines 171, respectively. The passivation layer 180 and the gate insulating layer 140 have a plurality of contact holes 181 exposing end portions 129 of the gate lines 121. The contact holes 181, 182, and 187 have inclined lateral sides, and the contact holes 187 are disposed in the opening of the color filters 231-233. Accordingly, the boundaries of the upper and the lower passivation layers 180a and 180b overlap each other. However, the surfaces of the color filters 231-233 are exposed through the contact holes 187 such that the contact holes 187 may have lateral sides of a stepped shape.

A plurality of pixel electrodes 190 and a plurality of contact assistants 81 and 82, which are preferably made of IZO or ITO, are formed on the passivation layer 180.

The pixel electrodes 190 are physically and electrically connected to the drain electrodes 175 through the contact holes 185 such that the pixel electrodes 190 receive the data voltages from the drain electrodes 175.

The pixel electrodes 190 supplied with the data voltages generate electric fields in cooperation with the common electrode on the other panel (not shown), which re-orient liquid crystal molecules in the liquid crystal layer 3 disposed therebetween.

As described above, a pixel electrode 190 and a common electrode form a liquid crystal capacitor, which stores applied voltages after turn-off of the TFT. An additional capacitor called a “storage capacitor,” connected in parallel to the liquid crystal capacitor, is provided for enhancing the voltage storing capacity. The storage capacitors are implemented by overlapping the pixel electrodes 190 with the storage lines 131. The capacitances of the storage capacitors, i.e., the storage capacitances, are increased by providing the expansions 137 at the storage electrode lines 131 for increasing overlapping areas, and by providing the expansions 177 of the drain electrode 175 (which are connected to the pixel electrodes 190 and overlap the expansions of the storage electrode lines 131) under the pixel electrodes 190 for decreasing the distance between the terminals. The storage capacitors may be implemented by overlapping the pixel electrodes 190 with the gate lines 121 adjacent thereto (called “previous gate lines”).

The pixel electrodes 190 overlap the gate lines 121 and the data lines 171 to increase the aperture ratio, but this is optional.

In this embodiment, the data lines 171 and the branches 139 of the storage lines are disposed between the pixel electrodes 190 adjacent thereto. Some side portions of the pixel electrodes 190 overlap a portion of the data lines 171, and the other side portions of the pixel electrodes 190 overlap a portion of the branches 139 of the storage electrode line 131. Portions of the data lines 171 overlap those portions of the branches 139 of the storage electrode line 131 that lie between adjacent pixel electrodes 190.

Accordingly, because the branches 139 block light leakage between the pixel electrodes 190, the widths of the data lines 171 may be minimized by the width overlapping with the branches 139 of the storage electrode lines 131, thereby decreasing the width of the data lines 171 in the range of about 50%. As a result, the areas overlapping the data lines 171 and the pixel electrodes 190 are decreased, thereby minimizing parasitic capacitance therebetween.

The contact assistants 81 and 82 are connected to the exposed end portions 129 of the gate lines 121 and the exposed end portions 179 of the data lines 171 through the contact holes 181 and 182, respectively. The contact assistants 81 and 82 are not requisites, but are preferred to protect the exposed portions 129 and 179 and to increase the adhesiveness of the exposed portions 129 and 179 to any external devices.

According to another embodiment of the present invention, the pixel electrodes 190 are made of a transparent conductive polymer. For a reflective LCD, the pixel electrodes 190 are made of an opaque reflective metal. In these cases, the contact assistants 81 and 82 may be made of a material such as IZO or ITO different from the pixel electrodes 190.

An LCD according to an embodiment of the present invention includes a TFT array panel as shown in FIGS. 1 and 2, a common electrode panel (not shown), and an LC layer interposed between two panels. The LCD may further include alignment layers formed on the two panels.

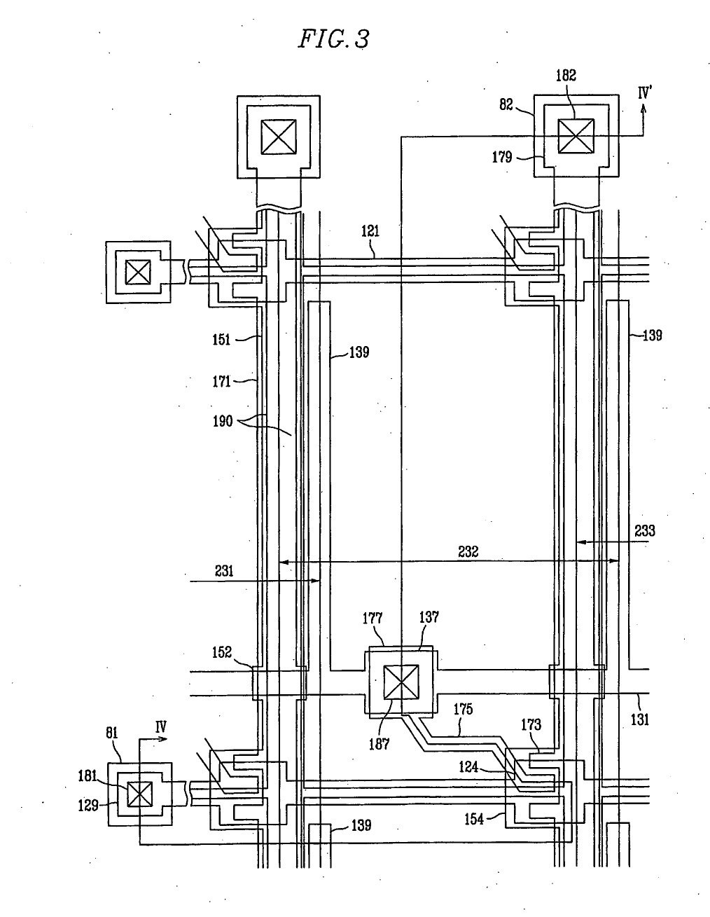

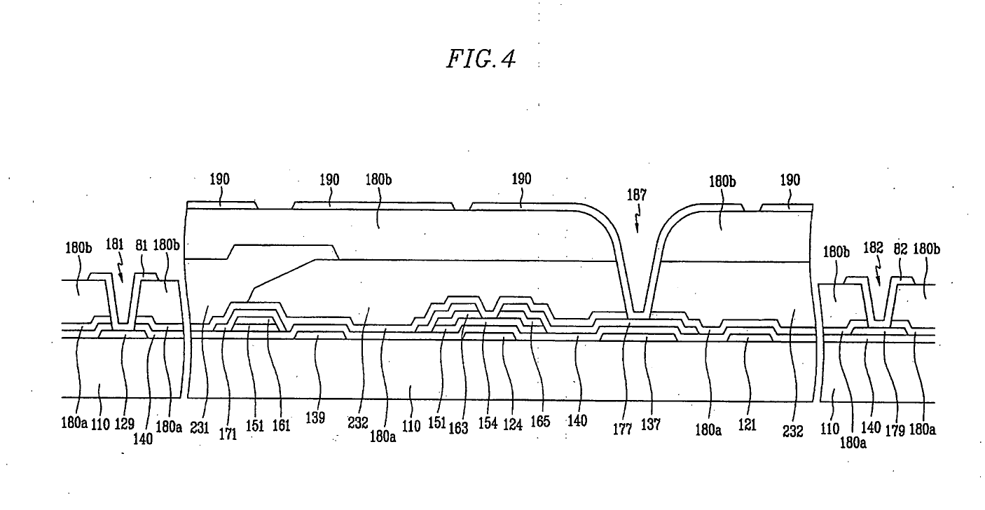

A TFT array panel for an LCD according to another embodiment of the present invention will be described in detail with reference to FIGS. 3 and 4.

FIG. 3 is a layout view of a TFT array panel of an LCD according to another embodiment of the present invention, and FIG. 4 is a sectional view of the TFT array panel shown in FIG. 3 taken along the line IV-IV′.

Referring to FIGS. 3 and 4, layered structures of the TFT panels according to this embodiment are almost the same as those shown in FIGS. 1 and 2.

A plurality of gate lines 121, including gate electrodes 124 and end portions 129 and a plurality of storage electrode lines 131 including expansions 137 and branches 139, are formed on a substrate 110. A gate insulating layer 140, a plurality of semiconductor stripes 151 including projections 154, and a plurality of ohmic contact stripes 161 including projections 163 and a plurality of ohmic contact islands 165 are then sequentially formed thereon. A plurality of data lines 171, including source electrodes 173 and end portions 179, and a plurality of drain electrodes 175 having expansions 177 on the storage electrode 135, are formed on the ohmic contacts 161 and 165 and on the gate insulating layer 140. A lower passivation layer 180a is then formed thereon. A plurality of color filters 231-233 are formed on the lower passivation layer 180a, and an upper passivation layer 180b is formed thereon. A plurality of contact holes 181, 182, and 187 are provided at the lower and upper passivation layers 180a and 180b, and/or at the gate insulating layer 140. A plurality of pixel electrodes 190 and a plurality of contact assistants 81 and 82 are formed on the upper passivation layer 180b.

Different from the TFT array panel shown in FIGS. 1 and 2, the branches 139 of the storage electrode lines 131, which are disposed between the pixel electrodes 190 adjacent thereto and overlap the portion of the pixel electrode 190, do not overlap the data lines 171. The space between the data lines 171 and the branches 139 of the storage electrode lines 131 is in the range of about 1 to 2 microns. As in the above description, the edge portions of the color filters 231-233, which overlap each other between the pixel electrodes 190, block light leakage between the pixels adjacent thereto. That is to say, because the branches 139 disposed between the pixel electrodes 190 and two portions of the color filters 231-233 overlapping each other completely block light leakage between the pixels adjacent thereto, it is not necessary that the data lines 171 fully cover the interval between the pixel electrodes 190 adjacent thereto. Accordingly, because the widths of the data lines 171 may be reduced by overlapping with the pixel electrodes 190, the areas overlapping the data lines 171 and the pixel electrodes 190 are decreased, thereby minimizing parasitic capacitance therebetween. Because the data lines 171 and the branches 139 do not overlap each other, a signal delay of the data lines 171 due to the parasitic capacitance therebetween is minimized.

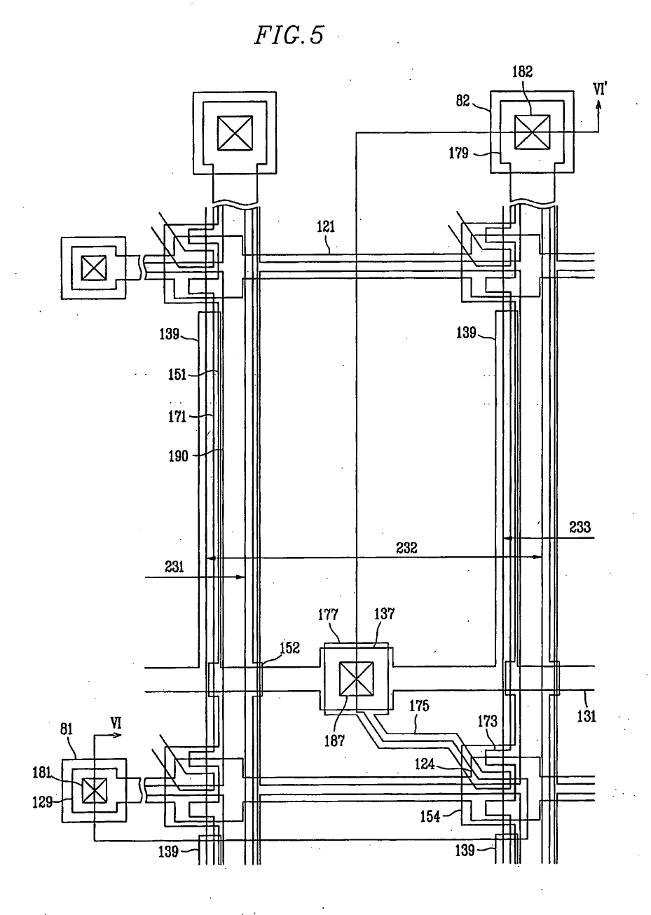

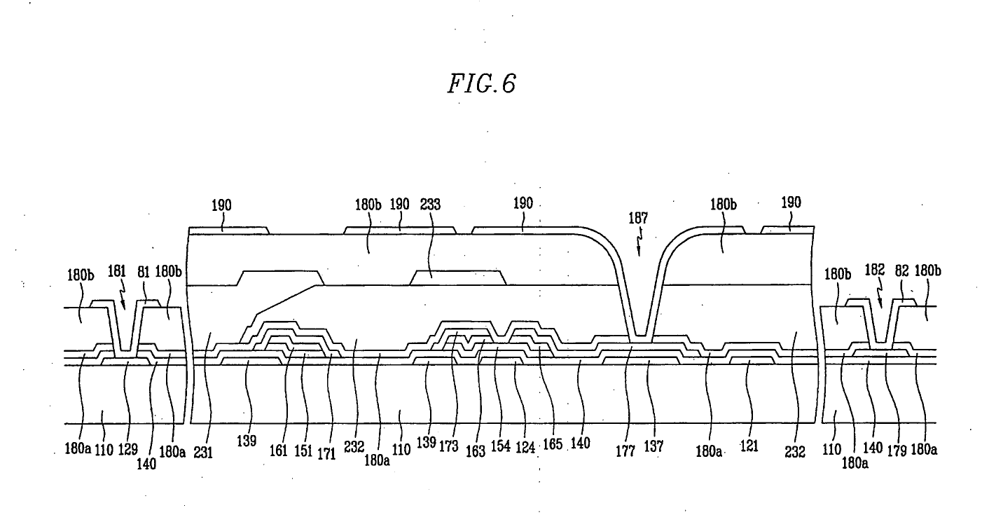

A TFT array panel for an LCD according to another embodiment of the present invention will be described in detail with reference to FIGS. 5 and 6.

FIG. 5 is a layout view of a TFT array panel of an LCD according to another embodiment of the present invention, and FIG. 6 is a sectional view of the TFT array panel shown in FIG. 5 taken along the line VI-VI′.

Referring to FIGS. 5 and 6, layered structures of the TFT panels according to this embodiment are almost the same as those shown in FIGS. 1 and 2.

A plurality of gate lines 121 including gate electrodes 124 and end portions 129, and a plurality of storage electrode lines 131 including expansions 137 and branches 139, are formed on a substrate 110. A gate insulating layer 140, a plurality of semiconductor stripes 151 including projections 154, and a plurality of ohmic contact stripes 161 including projections 163 and a plurality of ohmic contact islands 165 are then sequentially formed thereon. A plurality of data lines 171, including source electrodes 173 and end portions 179, and a plurality of drain electrodes 175 having expansions 177 on the storage electrode 135, are formed on the ohmic contacts 161 and 165, and on the gate insulating layer 140. A lower passivation layer 180a is then formed thereon. A plurality of color filters 231-233 are formed on the lower passivation layer 180a, and an upper passivation layer 180b is formed thereon. A plurality of contact holes 181, 182, and 187 are provided at the lower and upper passivation layers 180a and 180b, and/or the gate insulating layer 140. A plurality of pixel electrodes 190 and a plurality of contact assistants 81 and 82 are formed on the upper passivation layer 180b.

Different from the TFT array panel shown in FIGS. 1 and 2, the branches 139 of the storage electrode lines 131, which are disposed between the pixel electrodes 190 adjacent thereto and overlap a portion of the pixel electrode 190, are located at the left side of the data lines 171.

In this embodiment, because the branches 139 block light leakage between the pixel electrodes 190, the widths of the data lines 171 may be minimized by t overlapping with the branches 139 of the storage electrode lines 131, thereby decreasing the width of the data lines 171 in the range of about 50%. As a result, the areas overlapping the data lines 171 and the pixel electrodes 190 are decreased, thereby minimizing the parasitic capacitance therebetween.

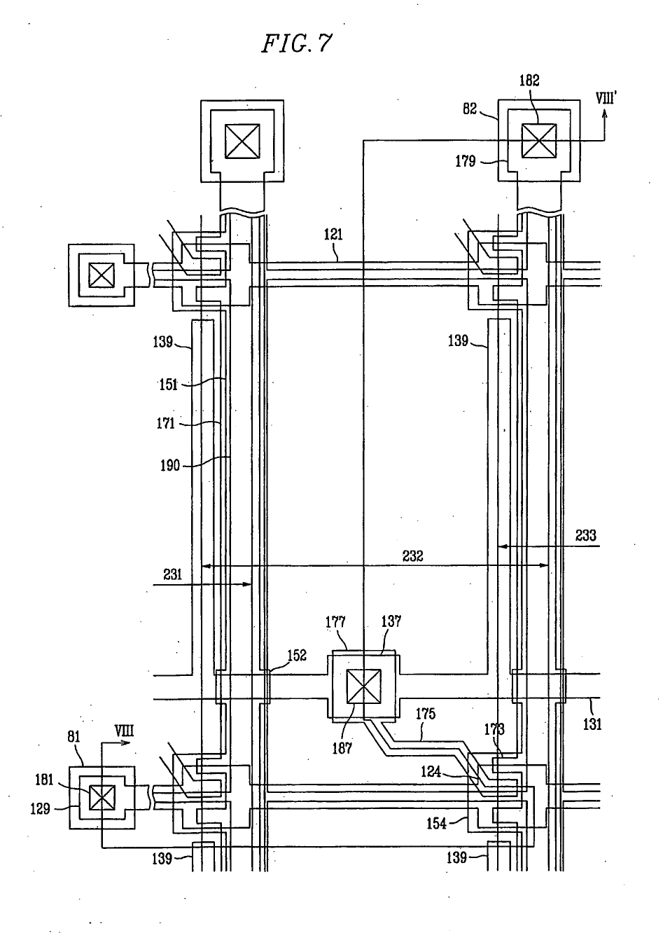

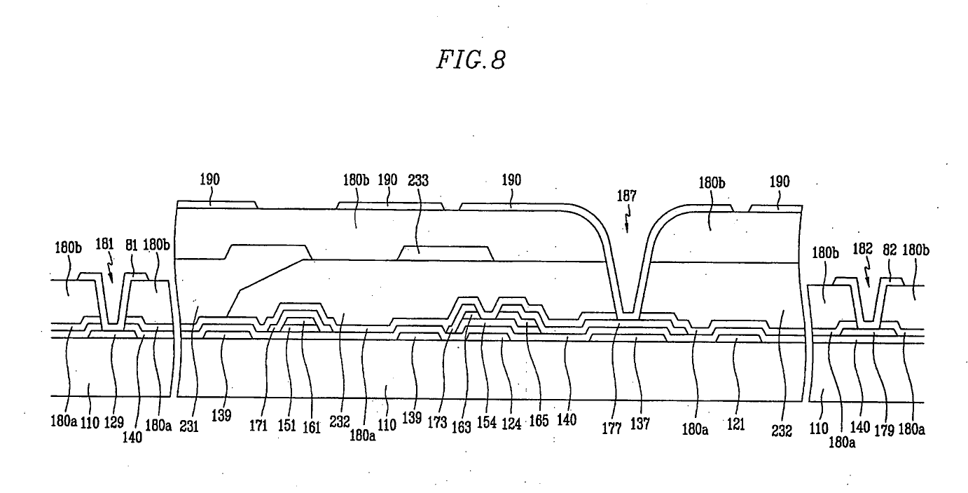

A TFT array panel for an LCD according to another embodiment of the present invention will be described in detail with reference to FIGS. 7 and 8.

FIG. 7 is a layout view of a TFT array panel of an LCD according to another embodiment of the present invention, and FIG. 8 is a sectional view of the TFT array panel shown in FIG. 3 taken along the line VIII-VIII′.

Referring to FIGS. 7 and 8, layered structures of the TFT panels according to this embodiment are almost the same as those shown in FIGS. 1 and 2.

A plurality of gate lines 121 including gate electrodes 124 and end portions 129, and a plurality of storage electrode lines 131 including expansions 137 and branches 139, are formed on a substrate 110. A gate insulating layer 140, a plurality of semiconductor stripes 151 including projections 154, and a plurality of ohmic contact stripes 161 including projections 163 and a plurality of ohmic contact islands 165 are then sequentially formed thereon. A plurality of data lines 171 including source electrodes 173 and end portions 179, and a plurality of drain electrodes 175 having expansions 177 on the storage electrode 135 are formed on the ohmic contacts 161 and 165, and on the gate insulating layer 140. A lower passivation layer 180a is then formed thereon. A plurality of color filters 231-233 are formed on the lower passivation layer 180a, and an upper passivation layer 180b is formed thereon. A plurality of contact holes 181, 182, and 187 are provided at the lower and the upper passivation layers 180a and 180b, and/or on the gate insulating layer 140. A plurality of pixel electrodes 190 and a plurality of contact assistants 81 and 82 are formed on the upper passivation layer 180b.

Different from the TFT array panel shown in FIGS. 1 and 2, the branches 139 of the storage electrode lines 131, which are disposed between the pixel electrodes 190 adjacent thereto and overlap the portion of the pixel electrode 190, do not overlap the data lines 171. The branches 139 of the storage electrode lines 131 are located at the left side of the data lines 171. Because the branches 139 disposed between the pixel electrodes 190 and two portions of the color filters 231-233 overlapping each other completely block light leakage between the pixels adjacent thereto, it is not necessary that the data lines 171 fully cover the interval between the pixel electrodes 190 adjacent thereto. Accordingly, because the widths of the data lines 171 may be reduced by overlapping with the pixel electrodes 190, the areas overlapping the data lines 171 and the pixel electrodes 190 are decreased, thereby minimizing the parasitic capacitance therebetween. Because the data lines 171 and the branches 139 do not overlap each other, the signal delay of the data lines 171 due to this parasitic capacitance is minimized.

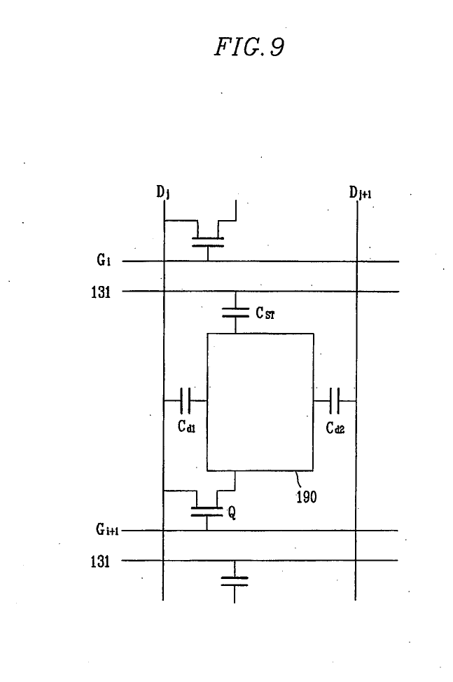

Referring to FIG. 9, a voltage variation of a pixel electrode due to the parasitic capacitance and the leakage current is described in detail.

FIG. 9 is an equivalent circuit diagram of a pixel, gate lines, data lines, and storage lines according to an embodiment of the present invention.

As shown in FIG. 9, a pixel electrode 190 is connected to gate lines Gᵢ₊₁ and Gᵢ and data lines Dⱼ₊₁ and Dⱼ through transistors Q, and parasitic capacitors C_{d1} and C_{d2} are formed between the pixel electrode 190 and the two data lines Dⱼ and Dⱼ₊₁. The capacitors and their capacitances are denoted with the same reference characters.

One of ordinary skill in the art will observe that the voltage variation ΔV of the pixel electrode 190 due to the parasitic capacitances C_{d1} and C_{d2} between the pixel electrode 190 and the data line Dⱼ+1 and Dⱼ can be expressed as:

$$Δ V = \frac{{C}_{d1} ( V 1 - {V 1}^{′} ) + {C}_{d2} ( V 2 - {V 2}^{′} )}{{C}_{LC} + {C}_{ST} + {C}_{d1} + {C}_{d2}} , \qquad ( 1 )$$

where V1 and V2 denote voltages of the data lines Dⱼ and Dⱼ+1 respectively, when the pixel electrode 190 are charged. V1′ and V2′ denote voltages of the respective data lines Dⱼ and Dⱼ₊₁ after the pixel electrode 190 are charged, C_{LC} denotes liquid crystal capacitance, and CST denotes storage capacitance.

If it is assumed that the LCD is subjected to an inversion, the data voltages in the data lines Dⱼ and Dⱼ₊₁ represent the same gray, and (V2−Vcom)=−(V1−Vcom) and (V2′−Vcom)=−(V1′−Vcom), then V2=V2′=V1=V1′. Accordingly, Equation 1 can be expressed as:

$$Δ V = \frac{2 {V}_{1} ( {C}_{d1} - {C}_{d2} )}{{C}_{LC} + {C}_{ST} + {C}_{d1} + {C}_{d2}} , \qquad ( 2 )$$

As described above, the voltage variation ΔV of the pixel electrode 190 is changed by the inversions of the data voltages V1 and V2 and the voltage variation ΔV is influenced by the differences of the parasitic capacitances C_{d1} and C_{d2}.

Accordingly, the parasitic capacitance of the data lines Dⱼ₊₁ and Dⱼ and the pixel electrode may be minimized by minimizing the overlapping area therebetween, increasing image quality by reducing factors such as stripes caused by the parasitic capacitances C_{d1} and C_{d2}.

Furthermore, the areas overlapping the data lines and the pixel electrodes are decreased by reducing the widths of the data lines, thereby minimizing the parasitic capacitance therebetween. Accordingly, poor quality of the LCD due to the parasitic capacitance may be prevented thereby enhancing the characteristics of the LCD.

While the present invention has been described in detail with reference to the preferred embodiments, those skilled in the art will appreciate that various modifications and substitutions can be made thereto without departing from the spirit and scope of the present invention as set forth in the appended claims.

What is claimed is:

1. A thin film transistor array panel comprising:
a gate line on an insulating substrate;
a storage electrode line on the insulating substrate;
a gate insulating layer over the gate line and the storage electrode line;
a semiconductor layer on the gate insulating layer;
a data line and a drain electrode on the semiconductor layer and separated from each other;
a lower passivation layer formed on the semiconductor layer and having a first contact hole exposing the drain electrode;
a color filter on the lower passivation layer;
an upper passivation layer on the color filter and having a second contact hole exposing the drain electrode; and
a pixel electrode connected to the drain electrode through the first and second contact holes;
wherein the storage electrode line has a light blocking member parallel to the data line.

2. The thin film transistor array panel of claim 1, wherein at least a portion of the light blocking member is disposed between pixel electrodes proximate thereto.

3. The thin film transistor array panel of claim 2, wherein a portion of the light blocking member overlaps the data line.

4. The thin film transistor array panel of claim 2, wherein the light blocking member does not overlap the data line.

5. The thin film transistor array panel of claim 4, wherein an interval between the data line and the light blocking member is in the range of about 1.0-2.0 microns.

6. The thin film transistor array panel of claim 2, wherein the light blocking member is disposed left of the data line.

7. The thin film transistor array panel of claim 2, wherein the light blocking member is disposed right of the data line.

8. The thin film transistor array panel of claim 1, wherein the storage electrode line is supplied with a common voltage.

9. The thin film transistor array panel of claim 1, wherein the upper passivation layer includes an organic material.

10. The thin film transistor array panel of claim 1, wherein adjacent portions of color filters overlap each other on the data line.

11. The thin film transistor array panel of claim 1, wherein the color filter is a primary color filter.

12. The thin film transistor array panel of claim 1, further comprising:
contact assistants respectively connected to the data and the gate lines through third and fourth contact holes, the third and fourth contact holes formed on the upper passivation layer.

13. The thin film transistor array panel of claim 1, further comprising:
an ohmic contact layer formed between the semiconductor and the data lines.

14. The thin film transistor array panel of claim 13, wherein the ohmic contact layer is extended generally along the data line.

15. The thin film transistor array panel of claim 1, wherein the storage electrode line overlaps the drain electrode.

16. The thin film transistor array panel of claim 15, wherein the storage electrode line has an expansion overlapping an expansion of the drain electrode.
